(19) United States
(12) Patent Application Publication
(10) Pub. No.: US 2017/0103797 A1
(43) Pub. Date: Apr. 13, 2017

(54) CALIBRATION METHOD AND DEVICE FOR DYNAMIC RANDOM ACCESS MEMORY

(71) Applicant: MediaTek Singapore Pte. Ltd., Singapore (SG)

(72) Inventor: Yong FANG, Shenzhen City (CN)

(21) Appl. No.: 15/284,786

(22) Filed: Oct. 4, 2016

(30) Foreign Application Priority Data
Oct. 8, 2015 (CN) 201510646689.X

(51) Int. Cl. G11C 11/4076; G11C 11/4096; G11C 29/04; G06F 3/06

(52) U.S. Cl. CPC G11C 11/4076; G06F 3/0604; G06F 3/0632; G06F 3/0685; G11C 11/4096; G11C 29/04

(57) ABSTRACT

A calibration method and a calibration device for dynamic random access memory are provided. The calibration method for the dynamic random access memory includes: performing a calibration on the dynamic random access memory; and storing a calibration result generated during the calibration into a data structure so that the calibration result can be read from the data structure; wherein the data structure includes: a calibration result data region, recording the calibration result generated by performing the calibration on the dynamic random access memory. In the calibration method, the boot time of the present invention can be greatly saved.

### CROSS REFERENCE TO RELATED APPLICATIONS

This application claims priority of China Patent Application No. 201510646689.X, filed on Oct. 8, 2015, the entirety of which is incorporated by reference herein.

### BACKGROUND OF THE INVENTION

Field of the Invention

The present invention relates to a calibration technique for memory, and in particular to a calibration method and a calibration device for dynamic random access memory (DRAM).

Description of the Related Art

The DRAM is a very important factor affecting the stability of the operating system of an electronic device. As a result, a calibration must be performed on the DRAM when the electronic device is booting.

The calibration of the DRAM is an optimization adjustment so that the software automatically matches the CPU of the platform, the dynamic random access memory, variations in voltage, the routing lines of the Printed Circuit Board (PCB), the temperature of the environment, and so on. Such adjustment comprises performing timing adjustment to various signal lines of DRAM, such as address lines, command lines, clock lines, data lines.

Using the conventional technique, a person skilled in the art can perform a malfunction analysis by analyzing the calibration log generated in the calibration of the DRAM when the electronic device malfunctions (for example, when the electronic device cannot be powered on). Specifically, a person skilled in the art may tear down the malfunctioning electronic device and weld a UART (Universal Asynchronous Receiver/Transmitter) interface to it. After the UART interface is welded to the malfunctioning electronic device, a calibration of the DRAM is performed, and the calibration log generated in the calibration of the DRAM is printed through the UART interface, so that the calibration log for the DRAM may be obtained.

Using the conventional technique, the calibration log generated in the calibration of the DRAM is printed through the UART interface, so it has the problem of the teardown of the electronic device and the welding of the UART interface. At the same time, a large amount of calibration log is printed through the UART interface, and this great quantity of data takes much more time to print than before. In addition, this method of printing the calibration logs of the DRAM through the UART interface can only print the current calibration log, and it cannot track back to previous calibration logs.

### BRIEF SUMMARY OF THE INVENTION

A calibration method and a calibration device for DRAM that reduces the boot time are provided.

A calibration method for a DRAM is provided. The method comprises: performing a calibration on the DRAM; and recording a calibration result generated during the calibration into a data structure, and the calibration result can be read from the data structure; wherein the data structure comprises a calibration result data region, for recording the calibration result generated by performing the calibration on the DRAM. The calibration result data region comprises a calibration result window region, a calibration result testing region, and a calibration result register region, the calibration result window region comprises at least one of a data strobe signal window, a command and address signal window, a data output signal window, and a data input signal window, and the calibration result testing region comprises at least one of a first testing result and a second testing result, wherein the first testing result is obtained by testing the calibration result in the manner of reading and writing the DRAM with CPU and the second testing result is obtained by testing the calibration result in the manner of reading and writing the DRAM with direct memory access, and the calibration result register region comprises at least one of an address of a register, first channel data of the register, and second channel data of the register.

The data structure further comprises a software information region, for storing information about the calibration software for performing the calibration on the DRAM; and a platform information region, for storing information about the platform for performing the calibration on the DRAM. The software information region comprises at least one of header information of the data structure, log information of the calibration software, and version information of the calibration software. The platform information region comprises at least one of CPU number, platform number, DRAM vendor identification, an operation rate of the dynamic random access memory, an operation voltage of the CPU, an operation voltage of the DRAM, a driving strength of the DRAM, a capacity organization of the DRAM, capacity information of the DRAM, and information about whether a complete testing has been performed on the DRAM.

The calibration method further comprises saving the data structure recording the calibration result into a non-volatile memory. The non-volatile memory comprises a first storage region, a second storage region and a third storage region. The first storage region is used for storing a first data structure which records a calibration result under a factory default state of the DRAM, the second storage region is used for storing a second data structure which records a calibration result under a normal state of the DRAM, and the third storage region is used for storing a third data structure which records a calibration result under an abnormal state of the DRAM.

The calibration method may further comprise transmitting the data structure stored in the non-volatile memory to a remote server by a wire network or a wireless network. And the calibration method may further comprises reading the data structure stored in the non-volatile memory through a USB interface and saving the data structure as a binary file; and parsing the binary file to obtain the calibration result. The calibration method may further comprise determining whether the calibration result for the DRAM is correct; and saving the data structure recording the calibration result into the non-volatile memory and/or outputting the calibration result recorded in the data structure to a printing device for printing, when the calibration result for the dynamic random access memory is abnormal. The calibration method may further comprise initializing the non-volatile memory before performing the calibration on the DRAM.

A calibration device for a dynamic random access memory (DRAM) is provided. The calibration device comprises a processor and a controller, the processor is used for performing calibration on the DRAM, and the controller is connected to the processor and used for recording a calibration result generated during the calibration into a data structure, such that the calibration result can be read from the data structure. The data structure comprises a calibration result data region, for recording the calibration result generated by performing the calibration on the DRAM. The calibration result data region comprises a calibration result window region, a calibration result testing region, and a calibration result register region. The calibration result window region comprises at least one of a data strobe signal window, a command and address signal window, a data output signal window, and a data input signal window, the calibration result testing region comprises at least one of a first testing result and a second testing result, wherein the first testing result is obtained by testing the calibration result in the manner of reading and writing the DRAM with CPU and the second testing result is obtained by testing the calibration result in the manner of reading and writing the DRAM with direct memory access, and the calibration result register region comprises at least an address of a register, first channel data of the register, and second channel data of the register.

The data structure may further comprise a software information region, for storing information about the calibration software for performing the calibration on the DRAM; and a platform information region, for storing information about the platform for performing the calibration on the DRAM. The software information region comprises at least one of header information of the data structure, log information of the calibration software, and version information of the calibration software.

The calibration device may further comprise a non-volatile memory connected with the controller, wherein the controller saves the data structure into the non-volatile memory. The non-volatile memory may comprise a first storage region, a second storage region and a third storage region. The first storage region is used for storing a first data structure which records a calibration result under a factory default state of the DRAM, the second storage region is used for storing a second data structure which records a calibration result under a normal state of the DRAM, and the third storage region is used for storing a third data structure which records a calibration result under an abnormal state of the DRAM. The calibration device may further comprise a determining module connected to the control module, and the determining module is used for determining whether the calibration result for the DRAM is correct, and when the calibration result for the dynamic random access memory is abnormal, the control module is used for saving the data structure which records the calibration result into the non-volatile memory and/or outputting the calibration result recorded in the data structure to a printing device for printing.

According to the present invention, the calibration result for the DRAM is recorded by the data structure, thus without the need of printing large amount of the calibration log of the DRAM. As a result, the boot time could be saved.

### BRIEF DESCRIPTION OF THE DRAWINGS

The present invention can be more fully understood by reading the subsequent detailed description and examples with references made to the accompanying drawings, wherein:

FIG. 1 is a flow schematic diagram of a calibration method for a DRAM according to a first embodiment of the present invention;

FIG. 2 is a structure schematic diagram of a data structure according to an embodiment of the present invention;

FIG. 3 is a flow schematic diagram of a calibration method for a DRAM according to a second embodiment of the present invention;

FIG. 4 is a flow schematic diagram of a calibration method for a DRAM according to third embodiment of the present invention;

FIG. 5 is a flow schematic diagram of a calibration method for a DRAM according to a fourth embodiment of the present invention;

FIG. 6 is a data schematic diagram of a calibration device for a DRAM according to a first embodiment of the present invention;

FIG. 7 is a data schematic diagram of a calibration device for a DRAM according to a second embodiment of the present invention;

FIG. 8 is a data schematic diagram of a calibration device for a DRAM according to a third embodiment of the present invention;

FIG. 9 is a data schematic diagram of a calibration device for a DRAM according to a fourth embodiment of the present invention.

### DETAILED DESCRIPTION OF THE INVENTION

The following description is of the best-contemplated operation of carrying out the invention. This description is made for the purpose of illustrating the general principles of the invention and should not be taken in a limiting sense. Certain terms and figures are used throughout the description and following claims to refer to particular components.

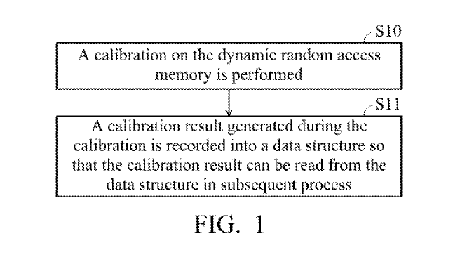

FIG. 1 is a flow schematic diagram of a calibration method for a DRAM according to a first embodiment of the present invention. As shown in FIG. 1, the calibration method for the DRAM comprises the following steps. The step S10 performs a calibration on the dynamic random access memory.

Generally, an electronic device, such as a tablet, a smart phone, and the like, is usually equipped with the dynamic random access memory. In order to make that the system of the electronic device can operate in stable and the dynamic random access memory can be adapted to different environmental factors (for example: different CPUs and the variations of the voltage), calibration of the dynamic random access memory needs to be performed. For example, every time the electronic device is booted, calibration of the DRAM is performed. Generally speaking, before performing the calibration on the dynamic random access memory, the CPU and the DRAM need to be initialized.

In step S11, a calibration result generated during the calibration is recorded into a data structure so that the calibration result can be read from the data structure in subsequent process.

In one embodiment of the present invention, a specific structure of the data structure can be previously defined before the calibration of the DRAM is performed. As a result, the data structure can be read directly, and then the corresponding information generated during the calibration is recorded (for example: filled in) into the corresponding position of the data structure when the calibration of the DRAM is performed.

In one embodiment of the present invention, because the calibration result is recorded into the data structure, the information quantity can be reduced so that it is convenient for users to store and view the data. Compared to the calibration result generated in a previous technique that needs to be printed, the boot time is greatly reduced.

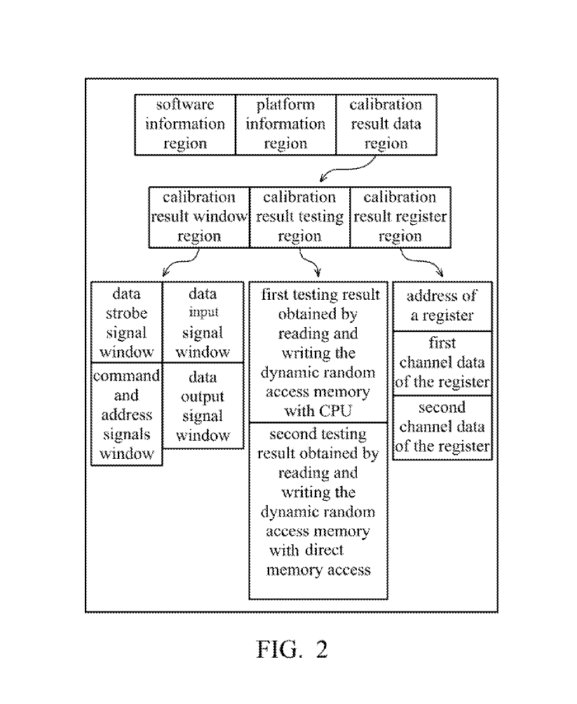

Specifically, the structure of the data structure can refer to the FIG. 2. First, the data structure comprises a calibration result data region, recording the calibration result generated in performing the calibration on the dynamic random access memory. The calibration result data region comprises a calibration result window region, a calibration result testing region, and a calibration result register region. The calibration result window region records a size of the signal window of the DRAM. The size of the signal window of the DRAM determines the quality of the signal of the DRAM. The calibration result testing region is used for performing reading and writing test on the DRAM by direct memory access (DMA) or reading and writing the DRAM with CPU, to determine whether the calibration result of the DRAM is correct. For example, write a certain data pattern into the DRAM with CPU or DMA, and then read the data pattern from the DRAM, and if the reading result is the same as the written data pattern, then the calibration result of the DRAM is determined to be correct, otherwise, the calibration result of the DRAM is determined to be not correct. The calibration result register region records the final value set into the register of the dynamic random access memory, and the final value is the optimal setting after the calibration of the dynamic random access memory.

The calibration result window region comprises at least one of a data strobe signal window, a command and address (CA) signals window, a data output signal window, and a data input signal window. Specifically, for the DRAM signal, each signal has its signal setup time and signal holding time. The sum of the signal setup time and the signal holding time (the signal setup time+the signal holding time) is the signal window of the signal. The size of the signal window determines the quality of the signal.

The calibration result testing region comprises at least one of a first testing result and a second testing result, wherein the first testing result is obtained by testing the calibration result in the manner of reading and writing the DRAM with CPU and the second testing result is obtained by testing the calibration result in the manner of direct memory access (DMA). Reading and writing the DRAM with CPU and through direct memory access are using two different kinds of hardware to test the DRAM respectively, so the calibration results described above can verify each other, for determining whether the calibration results for the DRAM are correct.

The calibration result register region comprises at least one of an address of a register (i.e., register address), first channel data of the register, and second channel data of the register. Specifically, the data recorded in the calibration result register region can be the value set into the register of the dynamic random access memory, and this value is the optimal setting obtained by the calibration of the dynamic random access memory.

In addition to the calibration result data region, the data structure further comprises: a software information region storing software information for performing the calibration on the dynamic random access memory; and a platform information region storing platform information for performing the calibration on the dynamic random access memory.

Specifically, the software information region comprises at least one of header information of the data structure, log information of calibration software, and version information of the calibration software. The platform information region comprises at least one of a CPU number, a platform number, a DRAM vendor identification, an operation rate of the dynamic random access memory, an operation voltage of the CPU, an operation voltage of the dynamic random access memory, a driving strength of the dynamic random access memory, a composition of the dynamic random access memory, the capacity of the DRAM and the information about whether a complete testing has been performed on the dynamic random access memory.

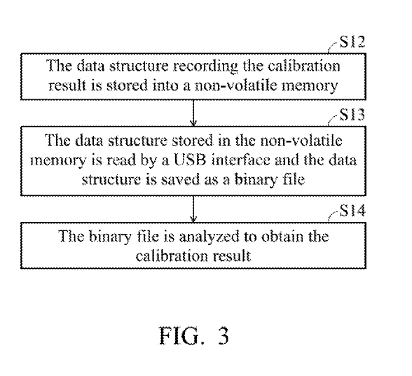

As shown in FIG. 3, the calibration method for the DRAM further comprises the following steps.

In step S12, the data structure recording the calibration result is stored into a non-volatile memory. The non-volatile memory is an embedded multimedia card (eMMC), a NAND flash, or a NOR flash.

In one embodiment of the present invention, the non-volatile memory may comprise a plurality of storage regions. The storage regions respectively store different data structures recording the calibration results in different states. For example, the different states may comprise an initial state (i.e., factory default state), a normal powered on state, and an abnormal state. Specifically, the non-volatile memory may comprise a first storage region, a second storage region and a third storage region. The first storage region stores a first data structure which records a calibration result under the factory default state of the DRAM. The second storage region stores a second data structure which records a calibration result under a normal state of the DRAM, and the third storage region stores a third data structure which records a calibration result under an abnormal state of the DRAM.

Because the calibration of the DRAM should be performed and the corresponding calibration result is obtained whenever the electronic device is booted. As a result, the first data structure stored in the first storage region, the second data structure stored in the second storage region and the third data structure stored in the third storage region are data structures of the same type, and indicate the calibration results under different states, respectively. For example, the electronic device may have been booted many times before leaving the factory. Namely, the DRAM has been calibrated many times. The calibration result generated by every calibration is recorded in a data structure, so the first data structure comprises a plurality of data structures recording calibration results generated by calibrating the DRAM before leaving the factory. In some embodiments, the first data structure may only comprise the data structure recording the last calibration result under the factory default state. Similarly, the second data structure comprises a plurality of data structures recording the correct calibration results for the DRAM. In addition, the second data structure may only comprise the data structure recording the last calibration result under the normal state. Similarly, the third data structure comprises a plurality of data structures recording the abnormal calibration results for the DRAM. In addition, the third data structure may only comprise the data structure recording the last calibration result under the abnormal state. In the embodiment of the present invention, because a plurality of storage regions of the non-volatile memory are utilized to store different data structures and the calibration results in different states for DRAM are recorded in the different data structures, the previous calibration records can be traced back, and it is more beneficial to analyze the states of the DRAM.

After step S12, the embodiment of the present invention further comprises the following steps.

In step S13, the data structure stored in the non-volatile memory is read by a USB interface and the data structure is saved as a binary file.

In step S14, the binary file is parsed to obtain the calibration result.

In the embodiment of the present invention, the electronic device and the server (for example, a computer) are connected (for example, the electronic device and the server are connected by the USB connector) when the calibration result further needs to be analyzed or viewed, and then the flash tool installed in the server is utilized to obtain the data structure from the non-volatile memory of the electronic device and the data structure is saved as a binary file, and then the binary file is parsed and restored to the calibration result by utilizing the analyzing tool installed in the server. For example, the flash tool may be a flash tool software and the analyzing tool may be a parser tool software.

In addition, after step S12, the embodiment of the present invention further comprises transmitting the data structure stored in the memory to a remote server by a wire network or a wireless network when the electronic device is network-connected.

As shown in the above embodiment, the embodiment of the present invention can save the data structure which records the calibration results into the non-volatile memory. The data structure stored in the non-volatile memory may be read through a USB interface when the data structure needs to be viewed, and the calibration result is then obtained by parsing the data structure. As a result, the calibration result may be viewed directly without the need of welding or tearing down of the device, and it is convenient and high efficiency. In addition, because the data structure recording the calibration result can be saved into the non-volatile memory, i.e., with a history-recording function, the calibration result of the initial state, the calibration result of the normal state and the calibration result of an abnormal state of the DRAM can be read. However, in the prior art, the calibration result is output to a printing device for printing by a UART interface, and it can only show the newest state of the platform without tracking back to the previous state.

Alternatively, after recording the calibration result generated during the calibration into the data structure (i.e., step S11), the calibration method may continue to determine whether the calibration result for the DRAM is correct. If the calibration result for the DRAM is abnormal, the data structure recording the calibration result is saved into the non-volatile memory and/or the calibration result recorded in the data structure is output to a printing device for printing. The calibration method for the DRAM ends directly if the calibration result for the DRAM is correct. In this way, the calibration result is not saved or printed when the calibration result for the DRAM is correct. As a result, it reduces storage costs and is more suitable for electronic devices with limited storage space.

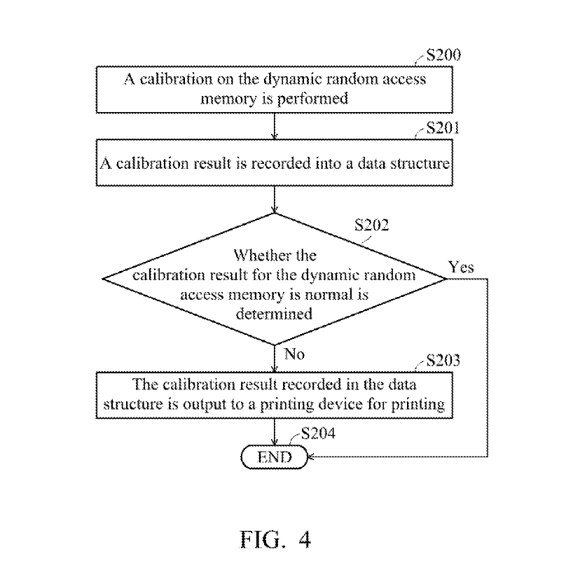

Specifically, as shown in FIG. 4, the calibration method for the DRAM comprises the following steps.

In step S200, a calibration on the DRAM is performed.

In step S201, a calibration result is recorded into a data structure.

In step S202, whether the calibration result for the DRAM is correct is determined. The calibration method goes to step S204 if the calibration result for the DRAM is correct, otherwise, goes to step S203.

In step S203, the calibration result recorded in the data structure is output to a printing device for printing.

In step S204, the calibration method for the DRAM is ended.

In the embodiment of the present invention, the calibration result is printed when the calibration result for the DRAM is abnormal. Because the calibration result recorded in the data structure is much less than the information quantity of the original calibration log, the information quantity for printing in the calibration method is reduced.

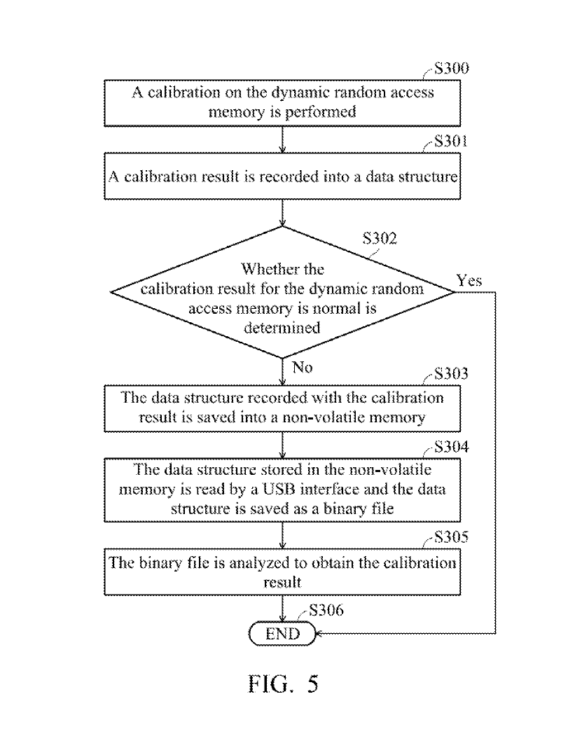

As shown in FIG. 5, the calibration method for the DRAM comprises the following steps according to another embodiment of the invention.

In step S300, a calibration on the DRAM is performed.

In step S301, a calibration result is recorded into a data structure.

In step S302, whether the calibration result for the DRAM is correct is determined. The calibration method goes to step S306 if the calibration result for the DRAM is correct, otherwise goes to step S303.

In step S303, the data structure recording the calibration result is saved into a non-volatile memory.

In step S304, the data structure stored in the non-volatile memory is read through a USB interface and saved as a binary file.

In step S305, the binary file is parsed to obtain the calibration result.

In step S306, the calibration method for the DRAM is ended.

The embodiment of the present invention can be applied to the system of the electronic device with less storage capacity. There is no need to save the data structure recording the calibration result when the calibration of the DRAM is correct. The data structure recording the calibration result is saved into the non-volatile memory only when the calibration of the DRAM is abnormal, thus convenient for the user to view and analyze.

In the embodiment of the present invention, the non-volatile memory is initialized before performing the calibration on the dynamic random access memory. In the conventional technique, the normal booting process of the electronic device is: performing initialization on the CPU of the electronic device, and then performing initialization on the DRAM of the electronic device, and finally, performing initialization on the non-volatile memory of the electronic device. In the normal booting process, the information or parameters during the process of the initialization is stored in the DRAM when the initialization process of the non-volatile memory is performed. In the above embodiments of the present invention, for the convenience during the calibration on the dynamic random access memory, the booting process of the electronic device is adapted appropriately when the electronic device is booting. Specifically, CPU of the electronic device is first initialized, and the non-volatile memory storing the data structure is initialized, and then the DRAM of the electronic device is initialized. Finally, the calibration of the DRAM is performed. Initializing the non-volatile memory first and then performing the calibration of the DRAM are convenient to save the data structure recording the calibration result into the non-volatile memory when the calibration of the DRAM is performed.

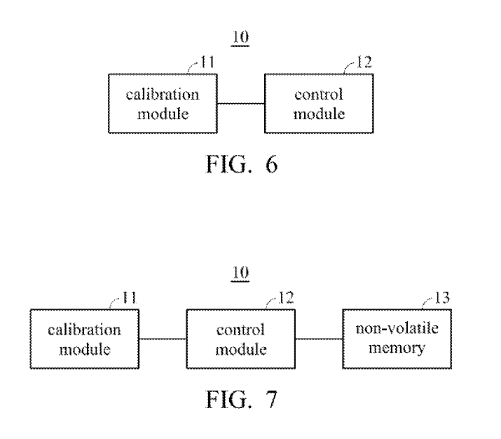

FIG. 6 is a schematic diagram of a calibration device for a DRAM according to a first embodiment of the present invention. As shown in FIG. 6, a calibration device 10 for a DRAM comprises a calibration module 11 and a control module 12. The calibration module 11 performs a calibration of the dynamic random access memory. The control module 12 is connected to the calibration module 11, and is arranged to record a calibration result generated during the calibration into a data structure, so that the calibration result can be read from the data structure. The calibration module may be implemented by a processor, microprocessor, etc which executes a calibration program stored in a non-volatile memory. And the control module may be implemented by a controller or microcontroller, etc.

The DRAM of the embodiment of the present invention is located in the electronic device. In order to make the system of the electronic device operate stably, the dynamic random access memory could be adapted to different environmental factors (for example, different CPUs and the variations of the voltage), and calibration of the dynamic random access memories is needed every time the electronic device is booted. Generally speaking, before performing the calibration on the dynamic random access memory, the CPU and the DRAM need to be initialized.

In one embodiment of the present invention, a specific structure of the data structure can be previously defined before the calibration of the DRAM is performed. As a result, the data structure can be read directly, and then the corresponding information generated during the calibration is recorded (for example, filled in) into the corresponding position of the data structure when the calibration of the DRAM is performed.

In one embodiment of the present invention, because the calibration result is recorded into the data structure by the control module 12, the information quantity can be reduced so that it is convenient for users to store and view the data. Compared to the calibration result that needs to be printed in a previous technique, the boot time is greatly reduced.

Specifically, the data structure comprises a calibration result data region for recording the calibration result generated by performing the calibration on the dynamic random access memory. The calibration result data region comprises a calibration result window region, a calibration result testing region, and a calibration result register region. The calibration result window region records a size of the signal window of the dynamic random access memory. The size of the signal window of the DRAM may determine the quality of the signal of the dynamic random access memory. The calibration result testing region is for testing whether the calibration result of the DRAM is correct by reading and writing the DRAM with CPU or direct memory access (DMA). The calibration result register region records the final value set into the register of the dynamic random access memory, and the final value is the optimal setting after the calibration of the dynamic random access memory.

The calibration result window region comprises at least one of a data strobe signal window, a command and address signal window, a data output signal window, and a data input signal window. Specifically, for the DRAM signal, each signal has its signal setup time and signal holding time. The sum of the signal setup time and the signal holding time (the signal setup time+the signal holding time) is the signal window of the signal. The size of the signal window may determine the signal quality.

The calibration result testing region comprises at least one of a first testing result and a second testing result, wherein the first testing result is obtained by testing the calibration result in the manner of reading and writing the DRAM with CPU, and the second testing result is obtained by testing the calibration result in the manner of direct memory access. Reading and writing the DRAM with CPU and through direct memory access are using two different kinds of hardware to test the dynamic random access memory, so the two calibration results described above can verify each other, for determining whether the calibration results for the DRAM are correct.

The calibration result register region comprises at least one of register address, first channel data of the register, and second channel data of the register. Specifically, the value recorded in the calibration result register region can be the value set into the register of the dynamic random access memory, and this value is the optimal setting after the calibration of the dynamic random access memory.

In addition to the calibration result data region, the data structure further comprises a software information region and a platform information region. The software information region stores software information for performing the calibration on the dynamic random access memory, and the platform information region stores platform information for performing the calibration on the dynamic random access memory.

Specifically, the software information region comprises at least one of header information of the data structure, log information of calibration software, and version information of the calibration software. The platform information region comprises at least one of CPU number, platform number, DRAM vendor identification, an operation rate of the dynamic random access memory, an operation voltage of the CPU, an operation voltage of the dynamic random access memory, a driving strength of the dynamic random access memory, a capacity organization of the dynamic random access memory, capacity of the dynamic random access memory, and the information about whether complete testing has been performed on the dynamic random access memory. The platform information region may further comprise indicator for indicating the current calibration processes to which step, thus convenient for users to calibrate the DRAM.

As shown in FIG. 7, the calibration device 10 further comprises the non-volatile memory 13 connected with the control module 12, the control module 12 saves the data structure which records the calibration result into the non-volatile memory 13, and the non-volatile memory 13 may be an embedded multimedia card, a NAND flash, or a NOR flash.

In one embodiment of the present invention, the non-volatile memory 13 may comprise a plurality of storage regions. The storage regions respectively store different data structures recording the calibration results in different states. For example, the different states may comprise an initial state (i.e., factory default state), a normal state, and an abnormal state. Specifically, the non-volatile memory may comprise a first storage region, a second storage region and a third storage region. The first storage region stores a first data structure which records the calibration result under the factory default state of the DRAM, the second storage region stores a second data structure which records a calibration result under a normal state of the dynamic random access memory, and the third storage region stores a third data structure which records a calibration result under an abnormal state of the dynamic random access memory.

Because the calibration of the DRAM need be performed and the corresponding calibration result is obtained whenever the electronic device is booted. As a result, the first data structure stored in the first storage region, the second data structure stored in the second storage region, and the third data structure stored in the third storage region are data structures of the same type, and indicate the calibration results under different states, respectively. For example, the electronic device may have been booted many times before leaving the factory. Namely, the DRAM has been calibrated many times. The calibration result generated by every calibration is recorded in a data structure, so the first data structure comprises a plurality of data structures recording calibration results generated by calibrating the DRAM many times before leaving the factory. In some embodiments, the first data structure may only comprise the data structure recording the last calibration result under the factory default state. Similarly, the second data structure may comprise a plurality of data structures recording a plurality of calibration results under the DRAM calibration normal state. In addition, the second data structure may only comprise the data structure recording the last calibration result under the normal state. Similarly, the third data structure comprises a plurality of data structures recording a plurality of calibration results under DRAM calibration abnormal state. In addition, the third data structure may only comprise the data structure recording the last calibration result under the abnormal state. In the embodiment of the present invention, because a plurality of storage regions of the non-volatile memory are utilized to store different data structures and the calibration results under different states for the DRAM are recorded in the different data structures, thus previous records can be traced back and it is more beneficial to analyze the states of the dynamic random access memory.

The calibration device 10 may further connect to a server 14 for reading the data structure stored in the non-volatile memory 13 through a USB interface of the DRAM, saving the data structure as a binary file, and parsing the binary file to obtain the calibration result. Specifically, the electronic device and the server 14 (for example, a computer) are connected, for example, through a USB connector, when the calibration result needs to be viewed or further analysis of the calibration result is needed, and then the flash tool installed in the server 14 is utilized to obtain the data structure from the non-volatile memory 13 of the electronic device and the data structure is saved as a binary file, and then the analyzing tool installed in the server 14 is utilized to parse and restore the binary file to the calibration result. For example, the flash tool may be flash tool software and the analyzing tool may be parser tool software.

In other embodiments of the present invention, the data structure stored in the non-volatile memory 13 may be transmitted to the server (remote server) 14 by a wire network or a wireless network when the electronic device is network-connected

In the embodiment of the present invention, the data structures recording the calibration results are further saved into the non-volatile memory 13 by the control module 12. The data structure stored in the non-volatile memory 13 can be read by the server (remote server) 14 through a USB interface when the data structure needs to be viewed, and the calibration result is obtained by analyzing data structure. As a result, the calibration result can be viewed directly without the need of welding and tearing down of the device, thus it is convenient and high efficiency. In addition, because the control module 12 can save the data structure recording the calibration result into the non-volatile memory 13, i.e., with a history-recording function, the calibration result recorded under the initial factory default state, the calibration result recorded under the normal state, and the calibration result recorded under an abnormal state of can be read. However, in the prior art, the calibration result is directly output to a printing device for printing through a UART interface, and only the newest state of the current platform can be shown without tracking back to previous states of the platform.

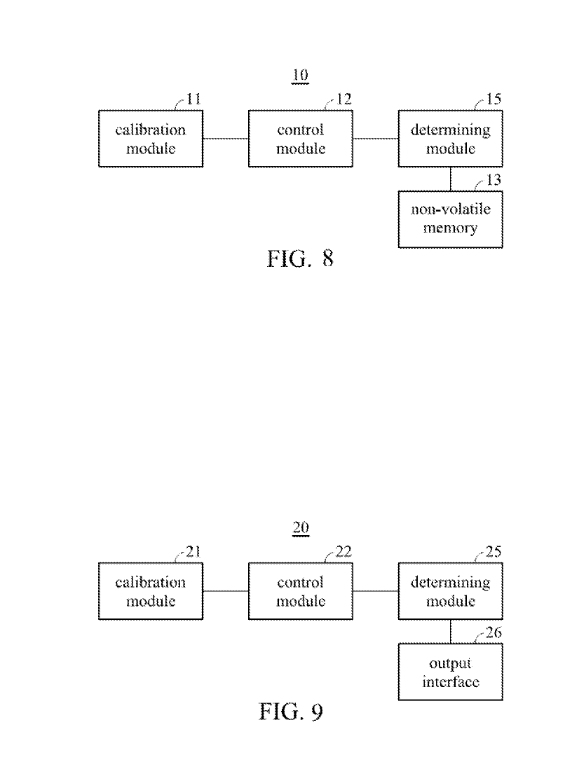

The calibration device 10 may further comprise a determining module and/or an output interface, and the determining module is arranged to determine whether the calibration result for the DRAM is correct. The control module is used for saving the data structure which records the calibration result into the non-volatile memory and/or outputting the calibration result recorded in the data structure to the output interface which then outputs the calibration result to a printing device for printing if the calibration result for the DRAM is abnormal. The control module ends the process directly if the calibration result for the DRAM is correct, and the detailed description is shown in FIG. 8 and FIG. 9.

As shown in FIG. 8, the calibration device 10 further comprises a determining module 15 connected between the control module 12 and the non-volatile memory 13, and the determining module 15 determines whether the calibration result for the DRAM is correct. The control module 12 stores the data structure recording the calibration result into the non-volatile memory 13 if the calibration result for the DRAM is abnormal; the control module 12 ends the process directly if the calibration result for the DRAM is correct. In this way, the control module 12 does not store or print the calibration result when the calibration result for the DRAM is correct, and the control module 12 stores or prints the calibration result only when the calibration result for the DRAM is abnormal. As a result, it can reduce storage costs and is more suitable for use in electronic devices with limited storage space.

FIG. 9 is a schematic diagram of a calibration device for a DRAM according to another embodiment of the present invention. As shown in FIG. 9, compared to the calibration device 10 in FIG. 6, the calibration device 20 further comprises a determining module 25 and an output interface 26, and the determining module 25 is connected to the control module 22 and determines whether the calibration result for the DRAM is correct, the control module 22 outputs the calibration result recorded in the data structure to the output interface 26 which then outputs the calibration result recorded in the data structure to the a printing device for printing if the calibration result for the DRAM is abnormal. The control module 22 ends the process directly if the calibration result for the DRAM is correct.

In the embodiment of the present invention, the calibration result is printed only when the calibration result for the DRAM is abnormal. Because the calibration result recorded in the data structure is much less than the information quantity of the original calibration log, it reduces the information amount of the printing.

Although embodiments of the present disclosure and their advantages have been described in detail, it should be understood that various changes, substitutions and alterations can be made herein without departing from the spirit and scope of the disclosure as defined by the appended claims.

What is claimed is:

1. A calibration method for a dynamic random access memory (DRAM), comprising:
performing a calibration on the DRAM; and
recording a calibration result generated during the calibration into a data structure; wherein the calibration result can be read from the data structure and the data structure comprises:
a calibration result data region, for recording the calibration result generated by performing the calibration on the DRAM.

2. The calibration method as claimed in claim 1, wherein the calibration result data region comprises a calibration result window region, a calibration result testing region, and a calibration result register region,
wherein the calibration result window region comprises at least one of a data strobe signal window, a command and address signal window, a data output signal window, and a data input signal window,
the calibration result testing region comprises at least one of a first testing result and a second testing result, wherein the first testing result is obtained by testing the calibration result in the manner of reading and writing the DRAM with CPU and the second testing result is obtained by testing the calibration result in the manner of reading and writing the DRAM with direct memory access, and
the calibration result register region comprises at least one of an address of a register, first channel data of the register, and second channel data of the register.

3. The calibration method as claimed in claim 1, wherein the data structure further comprises:
a software information region, for storing information about the calibration software for performing the calibration on the DRAM; and
a platform information region, for storing information about the platform for performing the calibration on the DRAM.

4. The calibration method as claimed in claim 3, wherein the software information region comprises at least one of header information of the data structure, log information of the calibration software, and version information of the calibration software.

5. The calibration method as claimed in claim 3, wherein the platform information region comprises at least one of CPU number, platform number, DRAM vendor identification, an operation rate of the dynamic random access memory, an operation voltage of the CPU, an operation voltage of the DRAM, a driving strength of the DRAM, a capacity organization of the DRAM, capacity information of the DRAM, and information about whether a complete testing has been performed on the DRAM.

6. The calibration method as claimed in claim 1, further comprising:
saving the data structure recording the calibration result into a non-volatile memory.

7. The calibration method as claimed in claim 6, wherein the non-volatile memory comprises:
a first storage region, for storing a first data structure which records a calibration result under a factory default state of the DRAM;
a second storage region, for storing a second data structure which records a calibration result under a normal state of the DRAM; and
a third storage region, for storing a third data structure which records a calibration result under an abnormal state of the DRAM.

8. The calibration method as claimed in claim 6, further comprising:
transmitting the data structure stored in the non-volatile memory to a remote server by a wire network or a wireless network.

9. The calibration method as claimed in claim 6, further comprising:
reading the data structure stored in the non-volatile memory through a USB interface and saving the data structure as a binary file; and
parsing the binary file to obtain the calibration result.

10. The calibration method as claimed in claim 1, further comprising:
determining whether the calibration result for the DRAM is correct; and
saving the data structure recording the calibration result into the non-volatile memory and/or outputting the calibration result recorded in the data structure to a printing device for printing, when the calibration result for the dynamic random access memory is abnormal.

11. The calibration method as claimed in claim 6, further comprising:
initializing the non-volatile memory before performing the calibration on the DRAM.

12. A calibration device for a dynamic random access memory (DRAM), comprising:
a processor, for performing calibration on the DRAM; and
a controller, connected to the processor, for recording a calibration result generated during the calibration into a data structure, wherein the calibration result can be read from the data structure;
wherein the data structure comprises:
a calibration result data region, for recording the calibration result generated by performing the calibration on the DRAM.

13. The calibration device as claimed in claim 12, wherein the calibration result data region comprises a calibration result window region, a calibration result testing region, and a calibration result register region,
wherein the calibration result window region comprises at least one of a data strobe signal window, a command and address signal window, a data output signal window, and a data input signal window,
the calibration result testing region comprises at least one of a first testing result and a second testing result, wherein the first testing result is obtained by testing the calibration result in the manner of reading and writing the DRAM with CPU and the second testing result is obtained by testing the calibration result in the manner of reading and writing the DRAM with direct memory access, and
the calibration result register region comprises at least an address of a register, first channel data of the register, and second channel data of the register.

14. The calibration device as claimed in claim 12, wherein the data structure further comprises:
a software information region, for storing information about the calibration software for performing the calibration on the DRAM; and
a platform information region, for storing information about the platform for performing the calibration on the DRAM.

15. The calibration device as claimed in claim 14, wherein the software information region comprises at least one of header information of the data structure, log information of the calibration software, and version information of the calibration software.

16. The calibration device as claimed in claim 12, further comprising:
a non-volatile memory, connected with the controller, wherein the controller saves the data structure into the non-volatile memory.

17. The calibration device as claimed in claim 16, wherein the non-volatile memory comprises:
a first storage region, for storing a first data structure which records a calibration result under a factory default state of the DRAM;
a second storage region, for storing a second data structure which records a calibration result under a normal state of the DRAM; and
a third storage region, for storing a third data structure which records a calibration result under an abnormal state of the DRAM.

18. The calibration device as claimed in claim 16, Wherein the processor further is used for determining whether the calibration result for the DRAM is correct; and
when the calibration result for the dynamic random access memory is abnormal, the controller is used for saving the data structure which records the calibration result into the non-volatile memory and/or outputting the calibration result recorded in the data structure to a printing device for printing.
